(19) United States
(12) Patent Application Publication
(10) Pub. No.: US 2026/0226372 A1
(43) Pub. Date: Aug. 6, 2026

(54) COMPOSITION FOR CLEANING PHOTORESIST PATTERN

(71) Applicant: DONGWOO FINE-CHEM CO., LTD., Iksan-si (KR)

(72) Inventors: Ji Min CHUN, Iksan-si (KR); Yonghwan Cho, Iksan-si (KR); Yerin Ryu, Iksan-si (KR)

(73) Assignee: DONGWOO FINE-CHEM CO., LTD., Iksan-si (KR)

(21) Appl. No.: 19/454,752

(22) Filed: Jan. 21, 2026

(30) Foreign Application Priority Data
Feb. 5, 2025 (KR) 10-2025-0014758

(51) Int. Cl. C11D 3/20

(52) U.S. Cl. CPC C11D 3/2093; C11D 3/201; C11D 3/2044; C11D 3/2079

(57) ABSTRACT

The present invention provides a composition for cleaning photoresist pattern including a monohydric alcohol compound, an ester compound with a specific structure, and water. The composition for cleaning photoresist pattern according to the present invention exhibits excellent cleaning power while preventing pattern collapse and damage during the cleaning of micro-patterns and minimizes the generation of impurities originating from the composition itself.

### CROSS REFERENCE TO RELATED APPLICATIONS

This application claims priority based on Korean Patent Application No. 10-2025-0014758, filed Feb. 5, 2025, the entire content of which is incorporated herein by reference in its entirety.

### TECHNICAL FIELD

The present invention relates to a composition for cleaning photoresist pattern, more specifically to a composition for cleaning photoresist pattern that exhibits excellent cleaning power while preventing pattern collapse and damage during the cleaning of micro-patterns with high aspect ratios and minimizes the generation of impurities originating from the composition itself.

### BACKGROUND ART

In photolithography processes used to form micro-structures in semiconductor manufacturing, the aspect ratio of patterns increases as line widths decrease. When the exposed area is cleaned with deionized water, which is commonly used after the development process, and then dried, pattern collapse may occur due to the capillary force of water droplets pulling on the micro-patterns during the drying process. To address this issue, a method for reducing pattern defects that occur during the cleaning and drying processes by using a cleaning solution with a lower surface tension after treatment with a developer is applied.

Furthermore, it has been reported that removing developer residue, which is not fully eliminated during the post-development cleaning step, enhances the resolution of the micro-patterns, thereby improving the overall process margin of the photolithography process. Consequently, the composition used in the cleaning step is required to possess adequate cleaning power to remove residue from the bottom surface of the photoresist pattern.

However, approaching from this perspective leads to the problem that the photoresist pattern, composed of organic compounds, particularly polymeric compounds, dissolves, causing the pattern itself to deform. Therefore, it is important that the cleaning composition does not cause damage to the photoresist pattern.

Korean Patent Publication No. 10-2017-0075438 discloses an example of a cleaning composition to prevent pattern collapse, which is a rinse solution for photolithography comprising a surfactant composed of a branched structure compound having a main chain containing a hydrophobic group and a plurality of side chains branched from the main chain and having at least one hydrophilic group-containing functional group, and deionized water.

However, the above rinse solution struggles to prevent pattern collapse when cleaning micro-patterns with high aspect ratios, and issues arise where the cleaned patterns become damaged or residual rinse solution components cause significant impurity generation.

### DISCLOSURE

### Technical Problem

An object of the present invention is to provide a composition for cleaning photoresist pattern that exhibits excellent cleaning power while preventing pattern collapse and damage during the cleaning of micro-patterns with high aspect ratios and minimizes the generation of impurities originating from the composition itself.

### Technical Solution

According to an aspect, the present invention provides a composition for cleaning photoresist pattern comprising a monohydric alcohol compound, a compound of the following formula (1), and water:

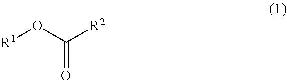

wherein,
R¹ is hydrogen or a C₁-C₅ alkyl,
R² is a C₂-C₅ alkyl, and
the total number of carbon atoms contained in R¹ and R² is 6 or less.

In one embodiment of the present invention, the monohydric alcohol compound may be a C₂-C₅ monohydric alcohol compound.

In one embodiment of the present invention, the monohydric alcohol compound may have an octanol/water partition coefficient (Log P) calculated by the following Equation 1 of −0.5 to 1.5:

$${K}_{ow} = {C}_{o} / {C}_{w} \qquad [ Equation 1 ]$$

(Cₒ: Concentration of alcohol compound in octanol, C_{w}: Concentration of alcohol compound in water)

$$Log P ( Partition Coefficient ) = Log ( {K}_{ow} ) .$$

In one embodiment of the present invention, the monohydric alcohol compound may be one or more selected from the group consisting of ethanol, 1-propanol, 1-pentanol, and 1-methoxypropanol.

In one embodiment of the present invention, the monohydric alcohol compound may be included in an amount of 0.1 to 20 wt % based on 100 wt % of the total composition.

In one embodiment of the present invention, the compound of the above formula (1) may be one or more selected from the group consisting of ethyl propionate, propyl propionate, butyl propionate, and propionic acid.

In one embodiment of the present invention, the compound of the above formula (1) may be included in an amount of 0.001 to 0.5 wt % based on 100 wt % of the total composition.

In one embodiment of the present invention, the water may be deionized water.

In one embodiment of the present invention, the composition for cleaning photoresist pattern may not contain either an alkaline compound or a fluoride.

### Advantageous Effects

The composition for cleaning photoresist pattern according to the present invention exhibits excellent cleaning power while preventing pattern collapse and damage during cleaning of micro-patterns with high aspect ratios, and minimizes the generation of impurities originating from the composition itself.

### BEST MODE

Hereinafter, the present invention will be described in more detail.

One embodiment of the present invention relates to a composition for cleaning photoresist pattern, comprising a monohydric alcohol compound, an ester compound having a specific structure, and water.

The composition for cleaning photoresist pattern according to the present invention, which comprises a monohydric alcohol compound and an ester compound having a specific structure, can prevent pattern collapse and damage during the cleaning of micro-patterns with high aspect ratios, while also removing development residues during the cleaning process, and minimize the generation of impurities originating from the composition itself.

Hereinafter, components of the composition for cleaning photoresist pattern according to one embodiment of the present invention are described in more detail.

In one embodiment of the present invention, the composition for cleaning photoresist pattern comprises a monohydric alcohol compound.

By including the monohydric alcohol compound, the composition for cleaning photoresist pattern according to the present invention allows the monohydric alcohol to dissolve in water and weaken hydrogen bonding between water molecules. Accordingly, the surface tension of water and the contact angle at the interface are reduced, thereby suppressing the phenomenon where the photoresist pattern collapses or is damaged during micro-pattern cleaning.

The monohydric alcohol compound used herein refers to an alcohol compound comprising a saturated hydrocarbon group having 1 to 12 carbon atoms and a single hydroxyl group.

In one embodiment of the present invention, the monohydric alcohol compound may be a C₂-C₅ monohydric alcohol compound.

In one embodiment of the present invention, the monohydric alcohol compound may have an octanol/water partition coefficient (Log P) calculated by the following Equation 1 of −0.5 to 1.5.

$${K}_{ow} = {C}_{o} / {C}_{w} \qquad [ Equation 1 ]$$

(Cₒ: Concentration of alcohol compound in octanol, C_{w}: Concentration of alcohol compound in water)

$$Log P ( Partition Coefficient ) = Log ( {K}_{ow} ) .$$

The partition coefficient is the ratio of concentrations of a compound in a mixture of two immiscible solvents at equilibrium. It can be used to predict the water dispersibility of a compound to be dissolved. A high partition coefficient indicates low water dispersibility, while a low partition coefficient indicates high water dispersibility.

If the partition coefficient is less than −0.5, it is difficult to expect an effect preventing pattern collapse during cleaning. If it exceeds 1.5, the photoresist pattern may be damaged by cleaning, or a large amount of impurities may be generated from the composition itself.

Monohydric alcohol compounds with the partition coefficient between −0.5 and 1.5 include, but are not limited to, ethanol, 1-propanol, 1-pentanol, 1-methoxypropanol, and the like.

In one embodiment of the present invention, the monohydric alcohol compound may be included in an amount of 0.1 to 20 wt %, preferably 0.5 to 10 wt %, based on 100 wt % of the total composition. If the content of the monohydric alcohol compound is less than 0.1 wt %, the effect of preventing pattern collapse during cleaning is negligible. If it exceeds 20 wt %, the photoresist pattern may be damaged or the pattern may dissolve, resulting in a low residual film rate, making it difficult to obtain a pattern with a high aspect ratio.

In one embodiment of the present invention, the composition for cleaning photoresist pattern comprises a compound of the following formula (1).

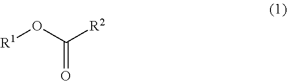

wherein,
R¹ is hydrogen or a C₁-C₅ alkyl,
R² is a C₂-C₅ alkyl, and
the total number of carbon atoms contained in R¹ and R² is 6 or less.

By using the compound of the above formula (1) along with a monohydric alcohol compound, the composition for cleaning photoresist pattern according to the present invention can lower the contact angle on the surface of the micro-pattern during cleaning after the photoresist development process, thereby preventing pattern collapse and minimizing damage to the photoresist pattern.

The term “C₁-C₅ alkyl” as used herein means a straight-chain or branched monovalent hydrocarbon having 1 to 5 carbon atoms, and examples includes, but are not limited to, methyl, ethyl, n-propyl, i-propyl, n-butyl, i-butyl, t-butyl, n-pentyl, and the like.

The term “C₂-C₅ alkyl” as used herein means a straight-chain or branched monovalent hydrocarbon having 2 to 5 carbon atoms, and examples includes, but are not limited to, ethyl, n-propyl, i-propyl, n-butyl, i-butyl, t-butyl, n-pentyl, and the like.

The compound of the above formula (1) may be one or more selected from the group consisting of ethyl propionate, propyl propionate, butyl propionate, and propionic acid, but is not limited thereto.

In one embodiment of the present invention, the compound of the above formula (1) may be included in an amount of 0.001 to 0.5 wt %, preferably 0.005 to 0.3 wt %, based on 100 wt % of the total composition. If the content is less than 0.001 wt %, it is difficult to expect the effect of preventing pattern collapse, and if it exceeds 0.5 wt %, there may be problems such as damage or dissolution of the photoresist pattern, resulting in a decrease in film thickness.

The composition for cleaning photoresist pattern according to one embodiment of the present invention includes water as a solvent, and the water may be included as a residual amount in addition to other components.

In one embodiment of the present invention, the water may be deionized water (DIW). Using deionized water reduces process costs and facilitates handling and wastewater treatment.

Furthermore, as mentioned above, since the water is included as a residual amount, the water content may vary when the content of the component(s) included in the composition for cleaning photoresist pattern changes.

Additionally, the composition for cleaning photoresist pattern of the present invention may further include conventional additives in addition to the aforementioned components to enhance its effectiveness.

The composition for cleaning photoresist pattern according to one embodiment of the present invention may not contain alkaline compounds or fluorides to minimize damage to the photoresist pattern.

The alkaline compounds may dissolve the photoresist pattern composed of polymeric components, causing pattern deformation and delamination, and the fluorides may remain after cleaning, increasing the occurrence of impurities.

The composition for cleaning photoresist pattern according to the present invention can be suitably used in the post-development cleaning process of the photoresist pattern and is particularly suitable for use as a rinse solution.

Hereinafter, the present invention will be described more specifically by means of Examples, Comparative Examples, and Experimental Examples. These Examples, Comparative Examples, and Experimental Examples are intended to illustrate the present invention only, and it is obvious to those skilled in the art that the scope of the present invention is not limited to them.

### Examples 1 to 22 and Comparative Examples 1 to 10: Preparation of Composition for Cleaning Photoresist Pattern

Compositions for cleaning photoresist pattern were prepared by mixing the components as shown in Table 1 and Table 2 (unit: wt %) below.

TABLE 1

| | Monohydric alcohol compound | | | | | | | Ester compound | | | | DIW |
|---|---|---|---|---|---|---|---|---|---|---|---|---|
| | A-1 | A-2 | A-3 | A-4 | A-5 | A-6 | A-7 | B-1 | B-2 | B-3 | B-4 | C |
| Example 1 | 3 | | | | | | | 0.05 | | | | 96.95 |
| Example 2 | | 3 | | | | | | 0.05 | | | | 96.95 |
| Example 3 | | | 3 | | | | | 0.05 | | | | 96.95 |
| Example 4 | | | | 3 | | | | 0.05 | | | | 96.95 |
| Example 5 | | | | | | | 3 | 0.05 | | | | 96.95 |
| Example 6 | | | 0.05 | | | | | 0.05 | | | | 99.9 |
| Example 7 | | | 0.1 | | | | | 0.05 | | | | 99.85 |
| Example 8 | | | 0.5 | | | | | 0.05 | | | | 99.45 |
| Example 9 | | | 1 | | | | | 0.05 | | | | 98.95 |
| Example 10 | | | 5 | | | | | 0.05 | | | | 94.95 |
| Example 11 | | | 10 | | | | | 0.05 | | | | 89.95 |
| Example 12 | | | 15 | | | | | 0.05 | | | | 84.95 |
| Example 13 | | | 20 | | | | | 0.05 | | | | 79.95 |
| Example 14 | | | 22 | | | | | 0.05 | | | | 77.95 |
| Example 15 | | 10 | | | | | | 0.001 | | | | 89.999 |
| Example 16 | | 10 | | | | | | 0.005 | | | | 89.995 |
| Example 17 | | 10 | | | | | | 0.3 | | | | 89.7 |
| Example 18 | | 10 | | | | | | 0.5 | | | | 89.5 |
| Example 19 | | 10 | | | | | | 0.7 | | | | 89.3 |
| Example 20 | | 10 | | | | | | | 0.5 | | | 89.5 |
| Example 21 | | 10 | | | | | | | | 0.5 | | 89.5 |
| Example 22 | | 10 | | | | | | | | | 0.5 | 89.5 |

TABLE 2

| Monohydric alcohol compound | | | | | | | Ester compound | | | | DIW |
|---|---|---|---|---|---|---|---|---|---|---|---|
| A-1 | A-2 | A-3 | A-4 | A-5 | A-6 | A-7 | B-1 | B-2 | B-3 | B-4 | C |

| | | | | | |
|---|---|---|---|---|---|
| Comparative | | | 10 | | 90 |
| Example 1 | | | | | |
| Comparative | | | 10 | 0.5 | 89.5 |
| Example 2 | | | | | |
| Comparative | | 10 | | 0.5 | 89.5 |
| Example 3 | | | | | |
| Comparative | 30 | | | | 70 |
| Example 4 | | | | | |
| Comparative | | | 100 | | 0 |
| Example 5 | | | | | |
| Comparative | 10 | | | | 90 |
| Example 6 | | | | | |
| Comparative | 10 | | 10 | | 80 |
| Example 7 | | | | | |
| Comparative | 10 | | | 1 | 89 |
| Example 8 | | | | | |
| Comparative | 10 | 10 | | | 80 |
| Example 9 | | | | | |
| Comparative | | | | 0.5 | 99.5 |
| Example 10 | | | | | |

A-1: Ethanol (LogP −0.18)
A-2: 1-Propanol (LogP 0.329)
A-3: 1-Pentanol (LogP 1.210)
A-4: 1-Methoxy-propanol (LogP −0.11)
A-5: Ethylene glycol (LogP −0.47)
A-6: Methanol (LogP −0.69)
A-7: Hexanol (LogP 2.03)
B-1: Ethyl propionate
B-2: Propyl propionate
B-3: Butyl propionate
B-4: Propionic acid

### Experimental Example 1

After forming the photoresist pattern according to the following method, a cleaning process was performed using the compositions for cleaning photoresist pattern of the above Examples and Comparative Examples, pattern collapse and pattern damage were then evaluated, and the results are shown in Tables 3 and 4 below.

### <Photoresist Pattern Formation and Cleaning Method>

A lower antireflection film (DUV42P-6, Nissan Chemical Industries) was spin-coated on a silicon substrate and then heated at 215° C. for 90 seconds to form a 600 Å thick film. A PHS-type photosensitive material (KTF-5664, Dongwoo Fine-Chem) was spin-coated on top to form a photoresist thin film, and then soft-baked in an oven at 100° C. for 60 seconds. After soft-baking, it was exposed using a scanner equipped with a KrF laser, and post-baked again in an oven at 110° C. for 60 seconds.

After completing post-baking, the wafer was immersed in a 2.38 wt % tetramethylammonium hydroxide (TMAH) aqueous solution for 60 seconds for development, followed by rinsing with deionized water to remove development residues. Then, 30 mL of the cleaning composition prepared in Examples and Comparative Examples was applied onto the surface of the silicon wafer for 10 seconds, and the wafer was dried by high-speed spinning to obtain a 180 nm L/S pattern.

### (1) Pattern Collapse

The degree of collapse of the 180 nm L/S pattern was observed using a CD-SEM (Hitachi) and evaluated according to the following evaluation criteria.

### <Evaluation Criteria>

∘: No pattern collapse
Δ: Collapse occurred only at the edge of the pattern
x: Collapse occurred at the edge and center of the pattern

### (2) Degree of Damage to the Photoresist Pattern

The difference in thickness of the photoresist pattern before and after treatment with the composition for cleaning photoresist pattern was measured using an FE-SEM (Hitachi) to confirm the degree of thickness reduction of the photoresist pattern, and the degree of damage to the photoresist pattern was evaluated according to the following evaluation criteria. The smaller difference in thickness of the photoresist pattern indicates less damage to the photoresist pattern.

### <Evaluation Criteria>

∘: Photoresist thickness reduction of 50 Å or less
Δ: Photoresist thickness reduction of more than 50 Å and less than or equal to 100 Å
x: Photoresist thickness reduction of more than 100 Å

### Experimental Example 2: Degree of Residual Particle Generation

The compositions for cleaning photoresist pattern of the Examples and Comparative Examples were filtered through a 0.01 m filter, then allowed to flow for about 30 minutes using a liquid particle counter <KS-18F> from Rion, and the number of particles sized 100 nm was measured. Evaluation was performed according to the evaluation criteria below, and the results are shown in Tables 3 and 4 below.

### <Evaluation Criteria>

∘: Less than 100 particles
Δ: 100 particles or more, less than 300 particles
x: 300 particles or more

TABLE 3

| | Pattern collapse | Pattern damage | Residual particles |
|---|---|---|---|
| Example 1 | ◯ | ◯ | ◯ |
| Example 2 | ◯ | ◯ | ◯ |
| Example 3 | ◯ | ◯ | ◯ |
| Example 4 | Δ | ◯ | ◯ |
| Example 5 | ◯ | Δ | Δ |
| Example 6 | Δ | ◯ | ◯ |
| Example 7 | ◯ | ◯ | ◯ |
| Example 8 | ◯ | ◯ | ◯ |
| Example 9 | ◯ | ◯ | ◯ |
| Example 10 | ◯ | ◯ | ◯ |
| Example 11 | ◯ | ◯ | ◯ |
| Example 12 | ◯ | ◯ | ◯ |
| Example 13 | ◯ | ◯ | ◯ |
| Example 14 | ◯ | Δ | ◯ |
| Example 15 | ◯ | ◯ | ◯ |
| Example 16 | ◯ | ◯ | ◯ |
| Example 17 | ◯ | ◯ | ◯ |
| Example 18 | ◯ | ◯ | ◯ |
| Example 19 | ◯ | Δ | ◯ |
| Example 20 | ◯ | ◯ | ◯ |
| Example 21 | ◯ | ◯ | Δ |
| Example 22 | ◯ | ◯ | ◯ |

TABLE 4

| | Pattern collapse | Pattern damage | Residual particles |
|---|---|---|---|
| Comparative | X | ◯ | ◯ |
| Example 1 | | | |
| Comparative | X | ◯ | ◯ |
| Example 2 | | | |
| Comparative | X | ◯ | ◯ |
| Example 3 | | | |
| Comparative | ◯ | X | ◯ |
| Example 4 | | | |
| Comparative | ◯ | X | ◯ |
| Example 5 | | | |
| Comparative | X | ◯ | ◯ |
| Example 6 | | | |
| Comparative | ◯ | X | X |
| Example 7 | | | |
| Comparative | ◯ | X | ◯ |
| Example 8 | | | |
| Comparative | Δ | Δ | X |
| Example 9 | | | |
| Comparative | X | ◯ | ◯ |
| Example 10 | | | |

As shown in Table 3 above, it was confirmed that the compositions for cleaning photoresist pattern of Examples 1 to 22, which contain monohydric alcohol compounds and ester compounds with a specific structure, can suppress pattern collapse during micro-pattern cleaning, prevent pattern damage, and suppress the generation of residual particles due to the components of the compositions.

In contrast, as shown in Table 4, the compositions for cleaning photoresist pattern of Comparative Examples 1 to 10 were found to either fail to prevent pattern collapse during micro-pattern cleaning, cause pattern damage, or generate a large amount of residual particles.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

1. A composition for cleaning photoresist pattern comprising a monohydric alcohol compound, a compound of formula (1), and water: 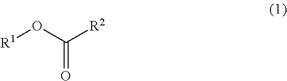
wherein,
R¹ is hydrogen or a C₁-C₅ alkyl,
R² is a C₂-C₅ alkyl, and
the total number of carbon atoms contained in R¹ and R² is 6 or less.

2. The composition for cleaning photoresist pattern according to claim 1, wherein the monohydric alcohol compound is a C₂-C₅ monohydric alcohol compound.

3. The composition for cleaning photoresist pattern according to claim 1, wherein the monohydric alcohol compound has an octanol/water partition coefficient (Log P) calculated by Equation 1 of −0.5 to 1.5:
$${K}_{ow} = {C}_{o} / {C}_{w} . \qquad [ Equation 1 ]$$
(Cₒ: Concentration of alcohol compound in octanol, C_{w}: Concentration of alcohol compound in water)
$$Log P ( Partition Coefficient ) = Log ( {K}_{ow} ) .$$

4. The composition for cleaning photoresist pattern according to claim 1, wherein the monohydric alcohol compound is one or more selected from the group consisting of ethanol, 1-propanol, 1-pentanol, and 1-methoxypropanol.

5. The composition for cleaning photoresist pattern according to claim 1, wherein the monohydric alcohol compound is included in an amount of 0.1 to 20 wt % based on 100 wt % of the total composition.

6. The composition for cleaning photoresist pattern according to claim 1, wherein the compound of formula (1) is one or more selected from the group consisting of ethyl propionate, propyl propionate, butyl propionate, and propionic acid.

7. The composition for cleaning photoresist pattern according to claim 1, wherein the compound of formula (1) is included in an amount of 0.001 to 0.5 wt % based on 100 wt % of the total composition.

8. The composition for cleaning photoresist pattern according to claim 1, wherein the water is deionized water.

9. The composition for cleaning photoresist pattern according to claim 1, wherein the composition does not contain either an alkaline compound or a fluoride.

10. A method comprising:
forming a photoresist pattern on a substrate by contacting an exposed photoresist layer with a developer; and
applying the composition of claim 1 to the photoresist pattern to remove development residues without causing pattern collapse of the photoresist pattern.
